(19) United States
(12) Patent Application Publication
(10) Pub. No.: US 2008/0308314 A1
(43) Pub. Date: Dec. 18, 2008

(54) Implementation structure of semiconductor package

(75) Inventor: Dai Sasaki, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/213,280

(22) Filed: Jun. 17, 2008

(30) Foreign Application Priority Data
Jun. 18, 2007 (JP) P2007-160341

(51) Int. Cl. H01R 12/04; H01L 21/00

(52) U.S. Cl. 174/263; 438/121; 257/E21.001

(57) ABSTRACT

An implementation structure of a semiconductor package includes: a printed wiring board which has via-holes piercing a mounted surface and an opposite surface of the printed wiring board; a via-land which is formed on the opposite surface so as to cover openings of the via-holes on the opposite surface and which is conductively connected to the via-holes; a semiconductor chip which has bumps; and a thermosetting adhesive filled between the semiconductor chip and the mounted surface of the printed wiring board, wherein an anisotropic conductive material is filled inside the via-holes, the bumps are inserted into the via-holes, and the bumps are conductively connected to the via-holes via the conductive particles.

### BACKGROUND OF THE INVENTION

1. Field of the Invention

The present invention relates to an implementation structure of a semiconductor package,

Priority is claimed on Japanese Patent Application No. 2007-160341, filed Jun. 18, 2007, the content of which is incorporated herein by reference.

2. Description of the Related Art

Recent years, integration of semiconductor elements has been increased every year, and due to such an improvement, high density, high performance, high speed, fine wirings, multiple layers, and the like have been developed. On the other hand, in order to increase density of the implemented semiconductor elements, it is necessary to achieve a small and thin package.

For example, conventional BGA (Ball Grid Array) and CSP (Chip Size Package) have a constitution in which semiconductor elements are implemented on a printed wiring board which has via-holes (via, through hole), the semiconductor elements and the printed wiring board are connected by using a wire bonding and/or a bump, and after that, a mounted side (on which wirings are mounted) of the printed wiring board is sealed with a resin. In such a case, it is possible to provide connection terminals on another side of the printed wiring board that is opposite from the mounted or implemented side through via-holes, hence, it is possible to provide multiple pins.

FIG. 9 is a drawing of a cross section showing a conventional constitution of an implemented flip chip. As shown in FIG. 9, in the conventional implementation constitution of a flip chip 10, multiple bumps 2 are formed on a semiconductor chip 1, and the semiconductor chip 1 is arranged facedown. In addition, the conventional implementation constitution of the flip chip 10 is a constitution in which a connection land 4 of a printed wiring board 3 is connected to the bumps 2, and the semiconductor chip 1 and the printed wiring board 3 are adhered by using a thermosetting adhesive 9.

The printed wiring board 3 includes: a connection land 4; a wiring pattern 6a which is lead from the connection land 4; a wiring pattern 6b formed on an opposite side surface 3b which is a back side of an mounted or implemented surface 3a of the printed wiring board 3 while the mounted surface 3a faces the semiconductor chip 1; ball terminals 5 formed on the wiring pattern 6b; and via-holes 7 for connecting the wiring pattern 6a and the wiring pattern 6b.

However, in the conventional implementation constitution of the flip chip 10, the wiring pattern 6a on the mounted surface 3a of the printed wiring board 3 is lead from the connection land 4, the wiring pattern 6a is connected to the wiring pattern 6b via the via-holes 7, and the wiring pattern 6b is lead to the ball terminal 5 on the opposite side surface 3b, hence, it is not possible to achieve short wirings.

Here, both Patent Document 1 (Japanese Patent Application, First Publication No. 2003-324126) and Patent Document 2 (Japanese Patent Application, First Publication No. 2002-260444) constitute implementation constitutions in which a conductive material is provided between a bump and via-hole in order to meet needs of achieving short wirings of a printed wring board.

However, in conventional semiconductor packages, there is a problem in which a connection is broken due to a stress generated from a difference between coefficients of linear thermal expansion of a semiconductor chip and a printed wiring board, and cannot have a implementation constitution which satisfies reliable connections of the semiconductor package.

### SUMMARY OF THE INVENTION

The present invention has been conceived in order to solve the above-described problems and has an objective to achieve both a shortened wirings from a semiconductor chip to a wiring pattern on an opposite side surface which is backside of a mounted surface of a printed wiring board and a reduced stress generated from a difference between coefficients of linear thermal expansion of a semiconductor chip and a printed wiring board. In accordance with the present invention, it is possible to provide a semiconductor package with high connection reliability that does not have connection breaks.

In order to achieve the above-described objectives, the present invention has, for example, following aspects.

A first aspect is an implementation structure of a semiconductor package including: a printed wiring board having a via-hole which pierces a mounted surface and an opposite surface of the printed wiring board; a via-land which is formed on the opposite surface of the printed wiring board while covering an opening portion of the via-hole and which is conductively connected to the via-hole; a semiconductor chip which has a bump for being implemented on the mounted surface; and an adhesive filled between the semiconductor chip and the mounted surface of the printed wiring board, wherein an anisotropic conductive material made from an conductive particle and an insulating resin is filled in the via-hole, the bump is inserted into the via-hole, and the bump and the via-hole are conductively connected via the conductive particle.

A second aspect is the above-described implementation structure of a semiconductor package, wherein the conductive particle conductively connects a top of the bump and the via-land.

A third aspect is the above-described implementation structure of a semiconductor package, wherein the via-hole is conductively connected to the via-land, and the via-hole is conductively connected to a side portion of the bump via the conductive particle.

A fourth aspect is the above-described implementation structure of a semiconductor package, wherein the via-hole is conductively connected to the via-land, and the via-hole includes a conductive portion which conductively touches a side portion of the bump.

A fifth aspect is the above-described implementation structure of a semiconductor package, wherein a diameter of the bump is smaller than a diameter of the via-hole.

A sixth aspect is the above-described implementation structure of a semiconductor package, wherein a height of the bump is larger than a depth of the via-hole.

A seventh aspect is the above-described implementation structure of a semiconductor package, wherein both a coefficient of linear thermal expansion of the adhesive and a coefficient of linear thermal expansion of an insulating resin included in the anisotropic conductive material are between a coefficient of linear thermal expansion of the semiconductor chip and a coefficient of linear thermal expansion of the printed wiring board.

As described above, in accordance with the semiconductor package of the above aspects, via-holes and bumps of a semiconductor chip are conductively connected, and the via-holes are conductively connected to via-lands provided on an opposite side of a mounted side of the printed wiring board, and therefore, it is possible to lead the wirings of the semiconductor chip to the opposite side of the printed wiring board via the via-holes and the via-lands. Therefore, it is possible to achieve short wirings, and it is possible to provide a semiconductor package which can meet needs for a high speed.

On the other hand, with regard to a stress generated from a difference between coefficients of linear thermal expansion of the semiconductor chip and the printed wiring board, the bumps and the via-holes are adhered via conductive particles with elasticity, hence, it is possible to reduce stress of connecting portions because of the conductive particles.

In addition, the semiconductor chip and the printed wiring board are adhered by using a thermosetting adhesive which has a low modulus of elasticity and which has a coefficient of linear thermal expansion between coefficients of linear thermal expansion of the semiconductor chip and the printed wiring board, hence, a stress affected on connection portions between the bumps and the via-holes is reduced by the thermosetting adhesive.

In accordance with the explanation above, it is possible to provide a semiconductor package with high connection reliability that does not have connection breaks between the bumps and the via-holes.

### BRIEF DESCRIPTION OF THE DRAWINGS

FIG. 1 is a cross section of a semiconductor package of an embodiment of the present invention.

FIG. 2A is a drawing which shows a enlarged cross section of a pin of a portion at which a bump and a via-hole are connected in the embodiment of the present invention.

FIG. 2B is a drawing which shows a enlarged cross section of a pin of a portion at which a bump and a via-hole are connected in the embodiment of the present invention.

FIG. 2C is a drawing which shows a enlarged cross section of a pin of a portion at which a bump and a via-hole are connected in the embodiment of the present invention.

FIG. 3 is a cross section showing a bump forming step of the embodiment of the present invention.

FIG. 4 is a cross section showing a resin supplying step of the embodiment of the present invention.

FIG. 5 is a cross section showing a resin supplying step of the embodiment of the present invention.

FIG. 6 is a cross section showing a resin supplying step of the embodiment of the present invention.

FIG. 7 is a cross section showing a bump connecting step of the embodiment of the present invention.

FIG. 8 is a cross section showing a bump connecting step of the embodiment of the present invention.

FIG. 9 is a cross section showing a conventional implementation constitution of an implemented flip chip.

### DETAILED DESCRIPTION OF THE INVENTION

Hereinafter, an embodiment of the present invention is explained in reference to the drawings.

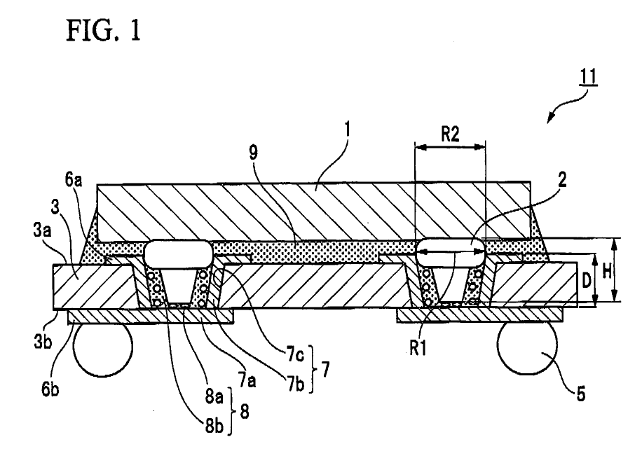

FIG. 1 is a cross section of a semiconductor package of an embodiment of the present invention.

As shown in FIG. 1, a semiconductor package 11 of this embodiment has a constitution in which a semiconductor chip 1 and a printed wiring board 3 are adhered by using a thermosetting adhesive 9.

In addition, the bump 2 of the semiconductor chip 1 is inserted into a via-hole 7 provided on the printed wiring board 3. Inside the via-hole 7, an anisotropic conductive material 8 is filled which includes conductive particles 8a. The conductive particles 8a are set in between the bump 2 and a via-land 7a and are pressed or crushed. Therefore, in such a constitution, the bump 2 and the via-land 7a are conductively connected via the conductive particles 8a.

As shown in FIG. 1, the bump 2 of this embodiment is provided at the semiconductor chip 1.

The bump 2 is preferably a metal bump, is more preferably a gold bump, and is furthermore preferably a gold stud bump. In addition, in this embodiment, as shown in FIG. 1, the bump 2 is inserted into the via-hole 7 as described below, and consequently, it is necessary that the bump 2 have a narrow head and it is necessary to control a height of the bump 2 so as to be tall, hence, it is preferable to use a gold stud bump in a shape of a drawing pin.

With regard to a bump diameter R1 of the bump 2, there is no specific limitation. However, for example, the bump diameter R1 is preferably in a range of 15-100 μm. This is because, if the bump diameter R1 is smaller than 15 μm, there is a difficulty for forming the bump 2. On the other hand, if the bump diameter R1 is larger than 100 μm, there is a difficulty for achiving a small and high density package. Therefore, with regard to the bump diameter R1 of the bump 2, a range of 15-100 μm is preferable, and a range of 20-80 μm is further preferable. It should be noted that it is preferable to form the bump diameter R1 of the bump 2 so as to be smaller than a via diameter R2 of the via-hole 7 provided on the printed wiring board 3.

With regard to a height H of the bump 2, there is no specific limitation. However, for example, the height H of the bump 2 is preferably in a range of 50-100 μm. In addition, it is preferable to form the bump 2 so as to have the height H which is higher than a depth D (almost same as a thickness of the printed wiring board 3) of the via-hole 7 provided on the printed wiring board 3. In addition, it is preferable to form the height H of the bump 2 while taking account of the depth D of the via-hole 7, amount of crush or compression of the bump 2 upon adhering, and a gap (standoff) between the semiconductor chip 1 and the printed wiring board 3 upon adhering.

For example, if the depth D of the via-hole 7 is 25 μm, amount of crush or compression is 5 μm, and the standoff is 50 μm it is possible to form the height H of the bump 2 so as to be 80 μm.

With regard to a pitch of the bump 2, there is no specific limitation. However, for example, the pitch is preferably a narrow pitch (for example, 0.4 mm or smaller). This is because a conventional implementation constitution can be applied if a bump pitch is 0.4 mm or larger. Therefore, the bump pitch is preferably 0.4 mm or smaller, and further preferably 0.2 mm or smaller.

With regard to the printed wiring board 3 of this embodiment, there is no specific limitation. However, for example, the printed wiring board 3 can be a multilayer buildup substrate, a flexible substrate and a rigid board, and is preferably a flexible substrate with a constitution in which the circuit is provided on both faces. In addition, by applying COF (chip on film) implementation on the flexible disc, it is possible to provide a semiconductor substrate which is appropriate for fine wirings that have 35 μm or smaller wiring pitch of inner lead

As shown in FIG. 1, the via-hole 7 of this embodiment is constituted from both a piercing aperture 7c provided on the printed wiring board 3 and a conductive portion 7b formed at an area which is at least an inside area of the piercing aperture 7c. In addition, on the opposite side surface 3b which is an opposite side of the mounted or implemented surface, a via-land 7a is formed so as to shut the piercing aperture 7c of the via-hole 7. The via-land 7a is conductively connected to the conductive portion 7b, and the via-land 7a is integrally formed with the wiring pattern 6b on the opposite side surface 3b which is an opposite side of the mounted surface. In addition, the leading portion 7b of the via-hole 7 is connected to the wiring pattern 6a on the mounted surface 3a.

Therefore, through the conductive portion 7b of the via-hole 7 and the via-land 7a, the wiring pattern 6a on a side of the mounted surface 3a of the printed wiring board 3 is conductively connected to the wiring pattern 6b on the opposite side surface 3b which is an opposite side of the mounted surface.

For example, as a material of the conductive portion 7b of the via-hole 7 and the via-land 7a, it is preferable to apply a metal such as Cu, Al, Au, Cr and Ti, and it is further preferable to apply Cu.

In addition, the via diameter R2 is preferably bigger than the bump diameter R1 and, for example, further preferable in a range of 30-120 μm.

As shown in FIG. 1, the anisotropic conductive material 8 of this embodiment is filled in the via-hole 7 provided on the printed wiring board 3. With regard to the anisotropic conductive material 8, there is no limitation. However, for example, it is preferable to apply an anisotropic conductive film (ACF) and an anisotropic conductive paste (ACP), and the anisotropic conductive paste (ACP) is more preferable because the anisotropic conductive material 8 is selectively filled only inside the via-hole 7.

As described below, the anisotropic conductive material 8 is made from both the conductive particles 8a and an insulating resin 8b which is a binder resin. As the insulating resin 8b, for example, it is possible to apply a synthetic rubber, thermosetting resin, and the like. In addition, in general, characteristics of the insulating resin 8b are necessary such as a high Tg (glass transition temperature), low water absorption and a low coefficient of linear thermal expansion.

In addition, in this embodiment, the insulating resin 8b has the coefficient of linear thermal expansion that is preferably in a range of 5-30 ppm/° C., and that is further preferably the approximately same as a thermosetting adhesive 9 described below while in a range between the coefficients of linear thermal expansion of the semiconductor chip 1 and the printed wiring board 3.

With regard to the conductive particles 8a, there is no limitation. However, for example, it is preferable to apply a metallic core such as nickel (Ni) and gold plated nickel, or it is preferable to apply a resin core that is a gold plated resin core such as styrene, acryl, and the like. In addition, with regard to the conductive particles 8a, it is especially preferable to apply a gold plated resin core because a high elasticity is necessary.

With regard to the conductive particles 8a, in general, not only an electrical conductivity is necessary, but also a shape, appropriate distribution and a particle size that never touch a pair of neighboring electrodes at the same time. In this embodiment, the conductive particles 8a are filled only inside the via-hole 7 and are covered with the thermosetting adhesive 9 described below, hence, there is a small possibility of a short circuit between a pair of the neighboring electrodes due to the spilled conductive particles 8a out of the via-hole 7.

With regard to a particle size of the conductive particles 8a, for example, it is preferable to be in a range of 3-10 μm. If the particle size of the conductive particles 8a is large, it is preferable because a difference of the particle size between before and after crushing or compressing the particle is large, that is, there is a large effect of reducing the stress which affects on a connecting portion such as between the bump and the via-land 7a. In addition, in order to avoid a short circuit between the neighboring electrodes when the conductive particles 8a spilled out of the via-hole 7, the particle size of the conductive particles 8a is preferably smaller than a gap between the semiconductor chip 1 and the printed wiring board 3.

In addition, for example, a content percentage of the conductive particles 8a included in the anisotropic conductive material 8 is preferably in a range of 5-15 vol %. If the content percentage of the conductive particles 8a included in the anisotropic conductive material 8 is high, there is a high possibility in which the conductive particles 8a are crushed or pressed between the bump 2 and the via-hole 7, and consequently, it is preferable because of a high reliability of connection.

As shown in FIG. 1, the thermosetting adhesive 9 of this embodiment is filled as an underfill resin between the semiconductor chip 1 and the printed wiring board 3, and adheres the semiconductor chip 1 and the printed wiring board 3 upon being cured by heating. With regard to the thermosetting adhesive 9, there is no limitation, and it is possible to be a liquid or a film.

In addition, the thermosetting adhesive preferably has a low modulus of elasticity and, for example, further preferably has a modulus of elasticity of 5 GPa or smaller.

In addition, a coefficient of linear thermal expansion of the thermosetting adhesive 9 is, for example, in a range of 5-30 ppm//° C. and further preferably between the coefficients of linear thermal expansion of the semiconductor chip 1 and the printed wiring board 3.

It should be noted that the thermosetting adhesive 9 has preferably the approximately same coefficient of linear thermal expansion as the insulating resin 8b included in the insulating resin 8b. In accordance with such a constitution, by applying a mixture of the thermosetting adhesive 9 and the anisotropic conductive material 8, it is possible to reduce stress generated from a difference between coefficients of linear thermal expansion of the semiconductor chip 1 and the printed wiring board 3, and consequently, it is possible to provide a semiconductor package with high connection reliability between the bump 2 and the via-hole 7.

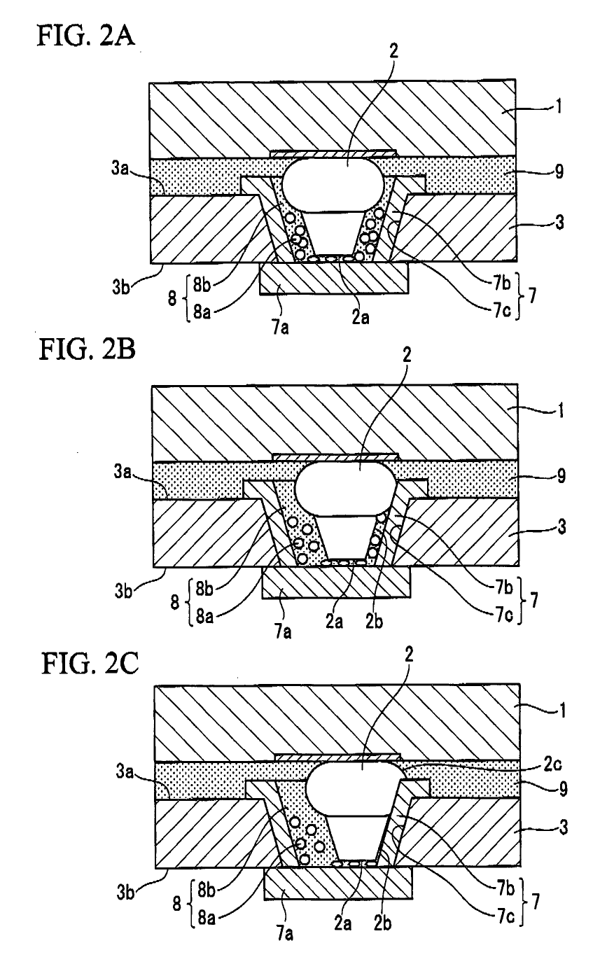

A connection portion between the bump 2 and the via-hole 7 of this embodiment is explained in reference to the drawings. FIGS. 2A-2C are drawings which show a enlarged cross section of a pin of a portion at which the bump 2 and the via-hole 7 are connected in this embodiment. As shown in FIG. 2A, if the bump 2 is inserted at a portion close to a center of the piercing aperture 7c which constitutes the via-hole 7, it is possible to obtain a good conductivity because the conductive particles 8a are crushed or pressed between a top portion of the bump 2 and the via-land 7a.

In addition, as shown in FIG. 2B, if the bump 2 is inserted into a position slightly deviated from a center of the piercing aperture 7c which constitutes the via-hole 7, the conductive particles 8a between a top portion of the bump 2 and the via-land 7a are crushed, and at the same time, the conductive particles 8a between a side face portion 2b of the bump 2 and the conductive portion 7b of the via-hole 7 are crushed.

In addition, as shown in FIG. 2c, if the bump 2 is inserted into a position greatly deviated from a center of the piercing aperture 7c which constitutes the via-hole 7, the conductive particles 8a between a top portion of the bump 2 and the via-land 7a are crushed, and at the same time, the deformed bump 2 touches the conductive portion 7b of the via-land 7 while no conductive particles 8a are slipped between a shoulder portion 2c of the bump 2 and the conductive portion 7b of the via-land 7.

As described above, with regard to the semiconductor package of this embodiment, it is possible to maintain a good conductivity even in a case in which there is a gap of alignment upon implementing or mounting the semiconductor chip 1, or in a case of out of alignment of a pitch between the bump 2 of the semiconductor chip 1 and the via-hole 7 of the printed wiring board 3.

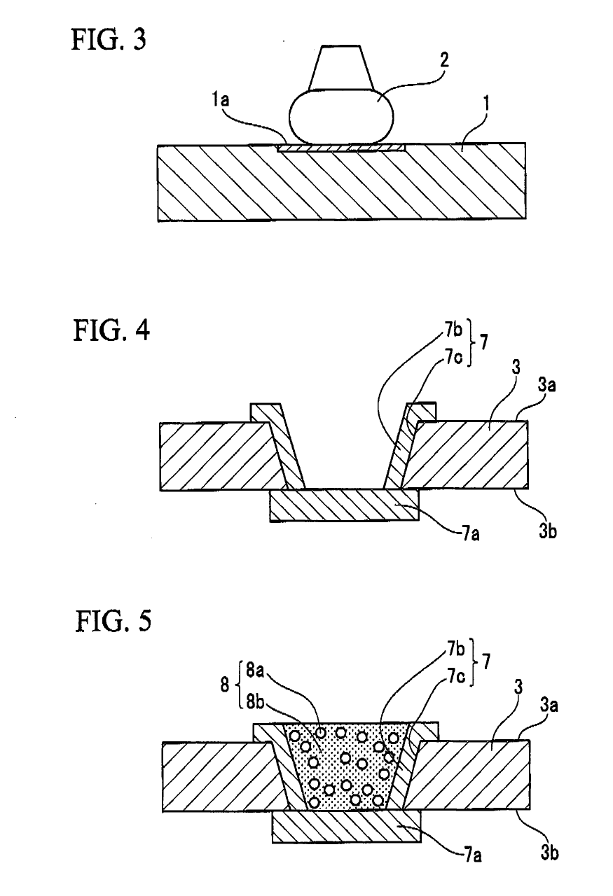

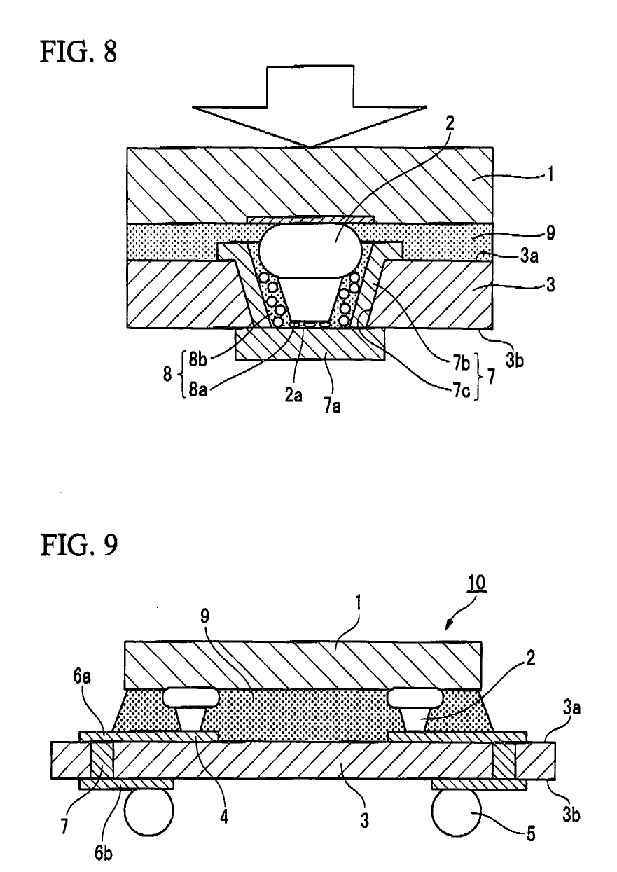

A production method of this embodiment is explained in reference to the drawings, FIGS. 3-8 are drawings for explaining the production method of the semiconductor package of this embodiment. FIG. 3 is a cross section showing a bump forming step. FIGS. 4-6 show a cross section showing a resin supplying step. FIGS. 7 and 8 are a cross section showing a bump connecting step.

It should be noted that the drawings are enlarged drawings of only one pin of multiple electrodes in order to explain the production method of this embodiment. Therefore, there is a possibility in which size, thickness, length, and the like of each of portions shown in the drawings are different from a concrete semiconductor package.

The semiconductor package production method if this embodiment is roughly constituted from a bump forming step, a resin supplying step and a bump connecting step. Hereinafter, each of the steps is explained one by one.

First, in the bump forming step, as shown in FIG. 3, the bump 2 is formed on an electrode pad 1a provided on the semiconductor chip 1.

With regard to a forming method of the bump 2, there is no limitation. However, it is possible to apply a gilding or coating method by using lithography, a method using supersonic, a method of heating, and the like.

For example, in the method using supersonic and the method of heating, it is possible to form a gold stud bump. In a concrete case, a gold ball is formed by causing a spark at an end of gold wire by using an electrode, and the gold ball is pushed so as to touch the electrode pat 1a of the semiconductor chip 1. Next, by applying supersonic, an intermetallic compound is generated between the gold ball and the electrode pad 1a. After this, the gold wire is pulled and cut, a leveling operation is conducted on the top of the intermetallic compound, and it is possible to obtain the gold stud bumps which have the same height and have flat and smooth surfaces on the top.

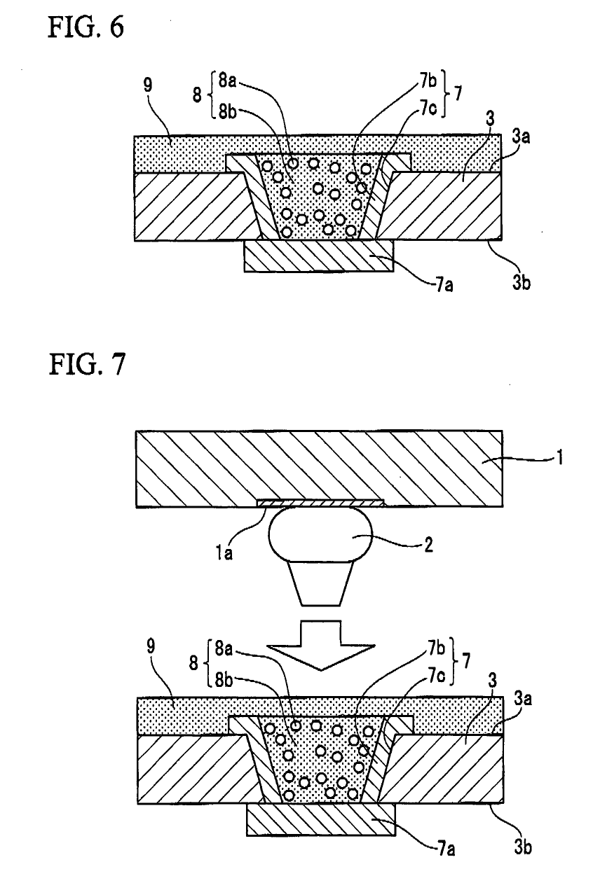

In the next resin supplying step, first, as shown in FIG. 4, the printed wiring board 3 is set in a manner in which the mounted surface 3a on which an opening portion of the via-hole 7 is provided faces upward and in which an opposite side face 3b which is an opposite side of the mounted surface and is a side of the via-land 7a faces downward, As shown in FIG. 5, next, the anisotropic conductive material 8 is filled inside the via-hole 7 of the printed wiring board 3. In this operation, it is preferable to fill the anisotropic conductive material 8 only inside the via-hole 7, and no conductive particle 8a of the anisotropic conductive material 8 remains in the mounted surface 3a which is outside the via-hole 7. In a concrete case, if the ACP is used as the anisotropic conductive material 8, it is possible to apply a method of, for example, injecting the anisotropic conductive material 8 only inside the via-hole 7 by using such as a dispenser, removing the ACP applied and remained on the mounted surface 3a of the printed wiring board 3 by using such as a solvent after filling the ACP inside the via-hole 7 by printing, As shown in FIG. 6, next, the thermosetting adhesive 9 is supplied to the mounted surface 3a of the printed wiring board 3 including the opening portion of the via-hole 7, Not only the resin of a paste, but also it is possible to used the resin of a film as the thermosetting adhesive 9. In a concrete case, it is possible to use NCP (Non Conductive Paste) as an example of the resin of a paste and NCF (Non Conductive Film) as an example of the resin of a film.

In the bump connecting step, finally, as shown in FIG. 7, the semiconductor chip 1 is arranged facedown so as to have the bump 2 that faces downward, and an alignment operation is conducted so as to adjust positions of both the bump 2 and the via-hole 7. As shown in FIG. 8, next, the semiconductor chip 1 is mounted on the printed wiring board 3 so as to insert the bump 2 into the via-hole 7. When the semiconductor chip 1 is pressed, the conductive particles 8a filled in the via-hole 7 are crushed or pressed between the bottom portion 2a of the bump 2 and the via-land 7a. After this, an heating operation is conducted in order to cure the insulating resin 8b of the anisotropic conductive material 8 and the thermosetting adhesive 9, and the semiconductor chip 1 and the printed wiring board 3 are adhered. For example, it is possible to apply an condition in which the semiconductor chip 1 is pressed with a pressure of 1 N/bump and is heated at 200° C.

As described above, it is possible to produce the semiconductor package 11 as shown in FIG. 1.

As described above, in accordance with this embodiment, the bump 2 of the semiconductor chip 1 and the via-hole 7 are conductively connected, and the via-hole 7 is conductively connected to the via-land 7a on the opposite side surface 3b which is an opposite side of the mounted surface. Therefore, it is possible to lead the wirings of the semiconductor chip 1 to the wiring 6b on the opposite side of the printed wiring board 3 via the via-hole 7 and the via-land 7a. Therefore, it is possible to shorten the wirings, and consequently, it is possible to provide the semiconductor chip 11 which can meet needs for a high speed.

On the other hand, with regard to a stress generated from a difference between coefficients of linear thermal expansion of the semiconductor chip 1 and the printed wiring board 3, the bumps 2 and the via-holes 7 are adhered via conductive particles 8a with elasticity, hence, it is possible to reduce stress of connecting portions because of the conductive particles 8a.

In addition, the semiconductor chip 1 and the printed wiring board 3 are adhered by using a thermosetting adhesive 9 which has a low modulus of elasticity and which has a coefficient of linear thermal expansion between coefficients of linear thermal expansion of the semiconductor chip 1 and the printed wiring board 3, hence, a stress affected on connection portions between the bumps 2 and the via-holes 7 is reduced by the thermosetting adhesive 9.

In addition, regardless of positions inside the via-hole 7 at which the bump 2 is inserted, it is possible to achieve a constitution for obtaining a reliable conductivity upon connecting the bump 2 and the via-hole 7.

In accordance with the explanation above, it is possible to provide the semiconductor package 11 with high connection reliability that does not have connection breaks between the bumps 2 and the via-holes 7.

In addition, the anisotropic conductive material 8 is supplied only inside the via-hole 7, and the opening portion of the via-hole 7 is covered with the thermosetting adhesive 9. Therefore, even if there is a case in which the conductive particles 8a is spilled out of the via-hole 7 when the bump 2 is pressed in order to be adhered, it is possible to avoid so much spilling of the conductive particles 8 that causes a short circuit between the neighboring terminals.

In accordance with the explanation above, it is possible to avoid a problem of conventional ACF connection or ACP connection, that is, a problem of a short circuit between the neighboring terminals, hence, it is possible to provide the semiconductor package 11 which is appropriate to a high density and appropriate to fine wirings.

As an application example of the present invention, it is possible to apply the present invention to all types of semiconductor packages that is constituted from a flip chip using conductive particles.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. An implementation structure of a semiconductor package comprising:
a printed wiring board having a via-hole which pierces a mounted surface and an opposite surface of the printed wiring board;
a via-land which is formed on the opposite surface of the printed wiring board while covering an opening portion of the via-hole and which is conductively connected to the via-hole;
a semiconductor chip which has a bump for being implemented on the mounted surface; and
an adhesive filled between the semiconductor chip and the mounted surface of the printed wiring board, wherein
an anisotropic conductive material made from an conductive particle and an insulating resin is filled in the via-hole, the bump is inserted into the via-hole, and the bump and the via-hole are conductively connected via the conductive particle.

2. An implementation structure of a semiconductor package according to claim 1, wherein the conductive particle conductively connects a top of the bump to the via-land.

3. An implementation structure of a semiconductor package according to claim 1, wherein the via-hole comprises a conductive portion which is conductively connected to the via-land, wherein the conductive portion is conductively connected to a side portion of the bump via the conductive particle.

4. An implementation structure of a semiconductor package according to claim 1, wherein the via-hole comprises a conductive portion which conductively touches a side portion of the bump.

5. An implementation structure of a semiconductor package according to claim 1, wherein a diameter of the bump is smaller than a diameter of the via-hole.

6. An implementation structure of a semiconductor package according to claim 1, wherein a height of the bump is larger than a depth of the via-hole.

7. An implementation structure of a semiconductor package according to claim 1, wherein both a coefficient of linear thermal expansion of the adhesive and a coefficient of linear thermal expansion of an insulating resin included in the anisotropic conductive material are between a coefficient of linear thermal expansion of the semiconductor chip and a coefficient of linear thermal expansion of the printed wiring board.

8. An implementation method of a semiconductor package comprising the steps of:
filling an anisotropic conductive material inside via-holes which pierce a printed wiring board;
supplying a thermosetting adhesive on a mounted surface of the printed wiring board;
mounting a semiconductor chip on the printed wiring board while inserting the bumps into the via-holes;
pressing at least one of the semiconductor chip and the printed wiring board; and
heating at least one of the semiconductor chip and the printed wiring board.
